(19) United States
(12) Patent Application Publication
(10) Pub. No.: US 2025/0311492 A1
(43) Pub. Date: Oct. 2, 2025

(54) METHOD FOR PRODUCING AN OPTOELECTRONIC COMPONENT, AND OPTOELECTRONIC COMPONENT

(71) Applicant: AMS-OSRAM INTERNATIONAL GMBH, Regensburg (DE)

(72) Inventors: Markus Leitl, Regensburg (DE); Benedikt Beer, Nittendorf (DE); Lavinia Israel, Regensburg (DE)

(21) Appl. No.: 18/864,831

(22) PCT Filed: Apr. 25, 2023
(86) PCT No.: PCT/EP2023/060805

§ 371 Date: Nov. 11, 2024

(30) Foreign Application Priority Data
May 17, 2022 (DE) 10 2022 112 355.3

(51) Int. Cl. H10H 20/857; H10H 20/01; H10H 20/851; H10H 20/855

(52) U.S. Cl. CPC H10H 20/857; H10H 20/0361; H10H 20/0363; H10H 20/0364; H10H 20/8514; H10H 20/855

(57) ABSTRACT

In an embodiment a method includes providing an optoelectronic semiconductor chip having an electrical contact pad arranged on a top side, connecting a bond wire to the electrical contact pad, forming a covering body on the electrical contact pad, wherein the covering body is limited to the electrical contact pad and does not cover other portions of the top side of the optoelectronic semiconductor chip, and wherein the bond wire is partially embedded in the covering body, and forming a wavelength-converting element on the top side of the optoelectronic semiconductor chip, wherein the covering body is at least partly covered by the wavelength-converting element.

### CROSS-REFERENCE TO RELATED APPLICATIONS

This patent application is a national phase filing under section 371 of PCT/EP2023/060805, filed Apr. 25, 2023, which claims the priority of German patent application no. 10 2022 112 355.3, filed May 17, 2022, each of which is incorporated herein by reference in its entirety.

### TECHNICAL FIELD

The present invention relates to a method for producing an optoelectronic device and to an optoelectronic device.

### BACKGROUND

It is known practice to equip optoelectronic devices with wavelength-converting elements. A known production method consists in spraying a wavelength-converting material onto the top side of an optoelectronic semiconductor chip.

### SUMMARY

Embodiments provide a method for producing an optoelectronic device. Further embodiments provide an optoelectronic device.

A method for producing an optoelectronic device comprises steps for providing an optoelectronic semiconductor chip having an electrical contact pad arranged on a top side, for forming a covering body on the electrical contact pad, wherein the covering body is limited to the electrical contact pad and does not cover other portions of the top side of the optoelectronic semiconductor chip, and for forming a wavelength-converting element on the top side of the optoelectronic semiconductor chip. In this case, the covering body is at least partly covered by the wavelength-converting element.

An advantage of this method is that the covering body formed on the electrical contact pad can protect the electrical contact pad from damage during the formation of the wavelength-converting element. Should the covering body be limited to the electrical contact pad, it advantageously does not prevent, or only slightly prevents, a heat conduction from the wavelength-converting element to the optoelectronic semiconductor chip.

In one embodiment of the method, a further step for connecting a bond wire to the electrical contact pad is carried out before the covering body is formed. In this case, the bond wire is partially embedded in the covering body. As a result of the bond wire being connected to the electrical contact pad before the covering body is formed, the covering body advantageously does not interfere with the production of the connection between the bond wire and the electrical contact pad.

In one embodiment of the method, the covering body is formed by a dispensing method, in particular by needle dispensing or by non-contact needle dispensing. Advantageously, this enables the formation of the covering body with well controllable position and size. In addition, this method advantageously allows the covering body to be produced without a bond wire connected to the electrical contact pad being damaged in the process.

In one embodiment of the method, the material of the covering body completely wets the electrical contact pad. For example, this can be achieved by targeted pre-treatment of the surface of the electrical contact pad. Advantageously, the method thus enables particularly precise control of the shape and size of the covering body formed on the electrical contact pad.

In one embodiment of the method, the wavelength-converting element is formed by a spray method. Advantageously, the covering body formed previously on the electrical contact pad can reduce a risk that the electrical contact pad is damaged during the spray method by particles accelerated in the direction of the electrical contact pad.

In one embodiment of the method, a further step for arranging the optoelectronic semiconductor chip on a top side of a carrier is carried out before the covering body is formed. In this context, the optoelectronic semiconductor chip is arranged in such a way that the top side of the optoelectronic semiconductor chip faces away from the top side of the carrier. In this case, the method additionally comprises a step for forming an embedding body on the top side of the carrier. In this case, side faces of the optoelectronic semiconductor chip are at least partly covered by the embedding body. Advantageously, the embedding body formed in this method can form a part of a housing of the optoelectronic device obtainable by the method.

In one embodiment of the method, the covering body and the embedding body are formed in a common operation. In this case, the covering body and the embedding body can be formed for example from the same material. Advantageously, this enables a particularly simple, fast and cost-effective implementation of the method.

In one embodiment of the method, this comprises an additional step for forming an optical lens over the wavelength-converting element. The optical lens can be used for beam shaping of the light radiated by the optoelectronic device.

An optoelectronic device comprises an optoelectronic semiconductor chip having an electrical contact pad arranged on a top side. A covering body is arranged on the electrical contact pad, wherein the covering body is limited to the electrical contact pad and does not cover other portions of the top side of the optoelectronic semiconductor chip. A wavelength-converting element is arranged on the top side of the optoelectronic semiconductor chip. The covering body is at least partly covered by the wavelength-converting element.

Advantageously, the covering body arranged on the electrical contact pad may have served to protect the electrical contact pad during the production of the wavelength-converting element. Thus, there advantageously is only a small risk of damage to the electrical contact pad of the optoelectronic semiconductor chip in this optoelectronic device. Should the covering body be limited to the electrical contact pad, it advantageously does not restrict, or only slightly restricts, a heat conduction from the wavelength-converting element to the optoelectronic semiconductor chip.

In one embodiment of the optoelectronic device, the electrical contact pad is completely covered by the covering body. Advantageously, the covering body thus enables a particularly comprehensive protection of the electrical contact pad of the optoelectronic semiconductor chip.

In one embodiment of the optoelectronic device, a bond wire is connected to the electrical contact pad. In this case, the bond wire is partially embedded in the covering body. Advantageously, the covering body does not affect the connection between the bond wire and the electrical contact pad.

In one embodiment of the optoelectronic device, the covering body comprises a silicone. Advantageously, such a covering body can ensure effective protection of the electrical contact pad.

In one embodiment of the optoelectronic device, the covering body comprises embedded particles, in particular particles comprising TiO₂ or ZrO₂. Advantageously, the covering body in this case comprises a high reflectivity, whereby the top side of the optoelectronic semiconductor chip of the optoelectronic device comprises a higher reflectivity than would be the case without the presence of the covering body.

In one embodiment of the optoelectronic device, the side faces of the optoelectronic semiconductor chip are at least partly covered by an embedding body. For example, the embedding body can form a part of a housing of the optoelectronic device or even the complete housing of the optoelectronic device.

In one embodiment of the optoelectronic device, an optical lens is arranged over the wavelength-converting element. The optical lens can be used for beam shaping of light radiated by the optoelectronic device.

### BRIEF DESCRIPTION OF THE DRAWINGS

The above-described properties, features and advantages of this invention and the way in which they are achieved will become clearer and more clearly understood in association with the following description of the exemplary embodiments which are explained in greater detail in association with the drawings, in which, in each case in a schematic illustration:

FIG. 1 shows a sectional side view of an optoelectronic semiconductor chip arranged on a carrier and having an electrical contact pad;

FIG. 2 shows the optoelectronic semiconductor chip after the connection to a bond wire;

FIG. 3 shows the optoelectronic semiconductor chip and the carrier after formation of an embedding body;

FIG. 4 shows the optoelectronic semiconductor chip after the formation of a covering body on the electrical contact pad;

FIG. 5 shows a plan view of the top side of the optoelectronic semiconductor chip;

FIG. 6 shows the optoelectronic semiconductor chip after the formation of a wavelength-converting element; and

FIG. 7 shows a sectional side view of an optoelectronic device formed from the arrangement after the formation of an optical lens.

### DETAILED DESCRIPTION OF ILLUSTRATIVE EMBODIMENTS

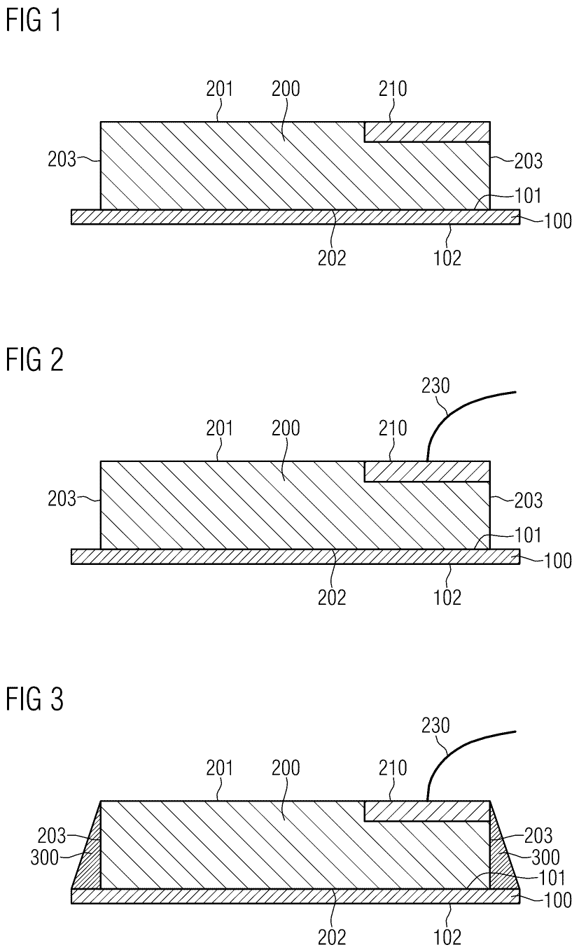

FIG. 1 shows a schematic sectional side view of an optoelectronic semiconductor chip 200. The optoelectronic semiconductor chip 200 comprises a top side 201 and an underside 202 opposite the top side 201. Side faces 203 of the optoelectronic semiconductor chip 200 are oriented substantially perpendicular to the top side 201 and the underside 202.

The optoelectronic semiconductor chip 200 is configured to emit electromagnetic radiation (light). The optoelectronic semiconductor chip 200 can be configured for example to emit light with a wavelength from the blue or ultraviolet spectral range.

The optoelectronic semiconductor chip 200 can be configured for example as a light-emitting diode chip (LED chip). The optoelectronic semiconductor chip 200 can be configured for example as a surface-emitting light-emitting diode chip. In this case, light is predominately emitted from the top side 201 of the optoelectronic semiconductor chip 200.

However, the optoelectronic semiconductor chip 200 may also be configured as a volume-emitting light-emitting diode chip. In this case, electromagnetic radiation is emitted from both the top side 201 and the side faces 203, and also from the underside 202 in some variants.

In the example shown in FIG. 1, the optoelectronic semiconductor chip 200 is arranged on a top side 101 of a carrier 100. The carrier 100 can also be referred to as a substrate. The carrier 100 may be a temporary carrier, which is detached from the optoelectronic semiconductor chip 200 again in a subsequent processing step. However, the optoelectronic semiconductor chip 200 may also remain permanently on the carrier 100. In this case, the carrier 100 can be formed for example as a circuit board, as a conductor frame, as a plastic carrier, as a metal-structured ceramic substrate or as a carrier made of a semiconductor material. In the example shown in FIG. 1, the carrier 100 comprises an underside 102 opposite the top side 101.

The optoelectronic semiconductor chip 200 is arranged on the top side 101 of the carrier 100, in such a way that the top side 201 of the optoelectronic semiconductor chip 200 faces away from the top side 101 of the carrier 100. The underside 202 of the optoelectronic semiconductor chip 200 faces the top side 101 of the carrier 100.

The optoelectronic semiconductor chip 200 comprises an electrical contact pad 210 on its top side 201. The electrical contact pad 210 can also be referred to as a bond pad. Voltage and electrical current can be applied to the optoelectronic semiconductor chip 200 via the electrical contact pad 210, in order that the optoelectronic semiconductor chip 200 emits electromagnetic radiation.

A further electrical contact pad of the optoelectronic semiconductor chip 200 may be formed on the underside 202 of the optoelectronic semiconductor chip 200. Should the optoelectronic semiconductor chip 200 remain permanently on the carrier 100, the electrical contact pad 210 on the underside 202 of the optoelectronic semiconductor chip 200 can be electrically conductively connected to a mating contact pad on the top side 101 of the carrier 100, for example using a solder connection or an electrically conductive adhesive connection.

FIG. 2 shows a schematic sectional side view of the carrier 100 and of the optoelectronic semiconductor chip 200 in a processing state that follows after the illustration in FIG. 1.

A bond wire 230 has been connected to the electrical contact pad 210 on the top side 201 of the optoelectronic semiconductor chip 200. The bond wire 230 provides an electrically conductive connection between the electrical contact pad 210 and a mating contact pad not shown in FIG. 2. The mating contact pad can be arranged for example on the top side 101 of the carrier 100.

FIG. 3 shows a schematic sectional side view of the optoelectronic semiconductor chip 200 and of the carrier 100 in a processing state that follows after the illustration in FIG. 2.

An embedding body 300 has been formed on the top side 101 of the carrier 100. For this purpose, the material forming the embedding body 300 has been arranged on the top side 101 of the carrier 100, for example using a dispensing method, for example by needle dispensing (dispensing) or by non-contact needle dispensing (jetting). The embedding body 300 thus formed covers the side faces 203 of the optoelectronic semiconductor chip 200 at least in part.

The material of the embedding body 300 can comprise for example a silicone. In addition, the material of the embedding body 300 can comprise reflective particles, for example particles comprising TiO₂ or ZrO₂.

It is possible to manage without the formation of the embedding body 300.

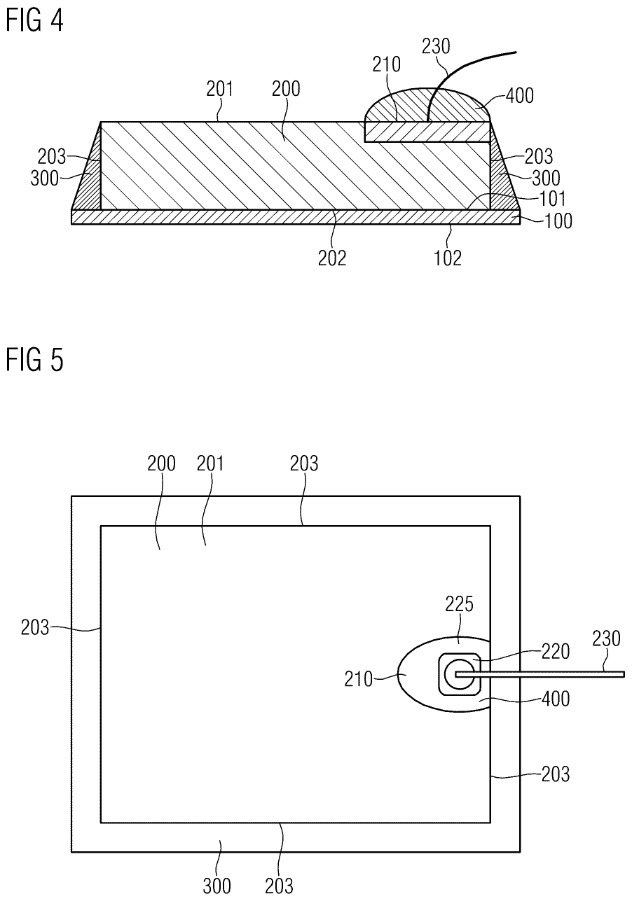

FIG. 4 shows a schematic sectional side view of the carrier 100, of the optoelectronic semiconductor chip 200, of the bond wire 230 and of the embedding body 300 in a processing state that follows after the illustration in FIG. 3.

A covering body 400 has been formed on the electrical contact pad 210 on the top side 201 of the optoelectronic semiconductor chip 200. For this purpose, the material of the covering body 400 has been arranged on the electrical contact pad 210, for example using a dispensing method, for example by needle dispensing (dispensing) or by non-contact needle dispensing (jetting).

The material of the covering body 400 can comprise for example a silicone. The material of the covering body 400 may also comprise embedded particles, in particular particles comprising TiO₂.

The covering body 400 and the embedding body 300 can be formed in a common operation. In this case, the embedding body 300 and the covering body 400 can have been formed for example from the same material. However, it is also possible to form the embedding body 300 and the covering body 400 in separate operations.

During the forming of the covering body 400 on the electrical contact pad 210, the bond wire 230 connected to the electrical contact pad 210 has been partially embedded in the covering body 400.

FIG. 5 shows a plan view of the top side 201 of the optoelectronic semiconductor chip 200 in the processing state shown in FIG. 4.

In the example shown, the electrical contact pad 210 on the top side 201 of the optoelectronic semiconductor chip 200 comprises a metallized region 220 and a passivation region 225 bounding the metallized region 220. The bond wire 230 is connected to the metallized region 220. The portion of the bond wire 230 connected to the metallized region 220 is embedded in the covering body 400.

It is advantageous for the covering body 400 arranged on the electrical contact pad 210 to completely cover the electrical contact pad 210. In this case, the covering body 400 covers both the metallized region 220 and the passivation region 225. However, it is also possible that the covering body 400 does not completely cover the electrical contact pad 210. The covering body 400 is limited to the electrical contact pad 210 and does not cover any other portions of the top side 201 of the optoelectronic semiconductor chip 200.

For example, a substantially complete covering of the electrical contact pad 210 by the covering body 400 and a limitation of the covering body 400 to the electrical contact pad 210 can be achieved by virtue of the wetting properties of the electrical contact pad 210, of the remaining portions of the top side 201 of the optoelectronic semiconductor chip 200 and of the material of the covering body 400 each being selected such that the material of the covering body 400 completely wets the electrical contact pad 210 but does not wet the remaining portions of the top side 201 of the optoelectronic semiconductor chip 200. In this case, during the formation of the covering body 400, the material of the covering body 400 can be applied in dispensed fashion, for example using a dispensing method, from the edge region of the top side 201 of the optoelectronic semiconductor chip 200 or from the top side of the embedding body 300 adjacent to the side faces 203 of the optoelectronic semiconductor chip 200 and can then wet the electrical contact pad 210 in the desired manner.

It is also possible to form the covering body 400 in such a way that it covers only the metallized region 220 of the electrical contact pad 210, but not the passivation region 225. It is also possible that the electrical contact pad 210 is not divided into a metallized region 220 and a bounding passivation region 225.

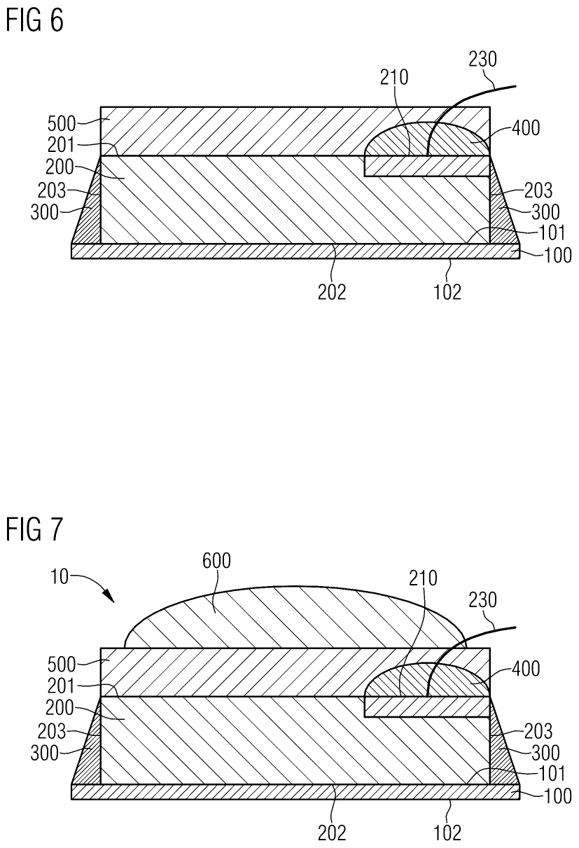

FIG. 6 shows a schematic sectional side view of the components also shown in FIG. 4, in a processing state that follows after the illustration in FIG. 4.

Starting from the processing state shown in FIGS. 4 and 5, a wavelength-converting element 500 has been formed on the top side 201 of the optoelectronic semiconductor chip 200. In the process, the covering body 400 has been at least partly covered by the wavelength-converting element 500. In the example shown in FIG. 6, the covering body 400 was completely covered by the wavelength-converting element 500. A portion of the bond wire 230 is embedded in the wavelength-converting element 500.

The wavelength-converting element 500 comprises a matrix material and wavelength-converting particles embedded in the matrix material. The matrix material can comprise for example a silicone.

The wavelength-converting element 500 is provided to convert at least some of the light radiated by the optoelectronic semiconductor chip 200 into light at another wavelength. For example, the wavelength-converting element 500 can be configured to convert light emitted by the optoelectronic semiconductor chip 200 with blue or ultraviolet light color into white light.

For example, the wavelength-converting element 500 may have been formed by a spray method. In this case, the material of the wavelength-converting element 500 was sprayed onto the top side 201 of the optoelectronic semiconductor chip 200. In this case, the wavelength-converting particles contained in the material of the wavelength-converting element 500 may have been incident on the top side 201 of the optoelectronic semiconductor chip 200 and on the covering body 400 at high speed. In the process, the covering body 400 has prevented damage to the electrical contact pad 210 of the optoelectronic semiconductor chip 200 on account of the incident particles.

FIG. 7 shows a schematic sectional side view of a part of an optoelectronic device 10, which has been formed by further processing of the components shown in FIG. 6.

Starting from the processing state shown in FIG. 6, an optical lens 600 has been formed over the wavelength-converting element 500. For example, the optical lens 600 may be formed by a molding method (mold method), for example by compression molding. The optical lens 600 can comprise for example a silicone.

The optical lens 600 is provided for shaping light emitted by the optoelectronic semiconductor chip 200 and converted by the wavelength-converting element 500, for example for causing the said light to converge or diverge. In the example shown, the optical lens 600 is formed as a converging lens.

In one alternative variant of the optoelectronic device 10, the optical lens 600 may be omitted.

The invention has been illustrated and described in detail on the basis of the preferred exemplary embodiments. Nevertheless, the invention is not restricted to the examples disclosed. A person skilled in the art is able to derive other variations.

1.-15. (canceled)

16. A method for producing an optoelectronic device, the method comprising:
providing an optoelectronic semiconductor chip having an electrical contact pad arranged on a top side;
connecting a bond wire to the electrical contact pad;
forming a covering body on the electrical contact pad, wherein the covering body is limited to the electrical contact pad and does not cover other portions of the top side of the optoelectronic semiconductor chip, and wherein the bond wire is partially embedded in the covering body; and
forming a wavelength-converting element on the top side of the optoelectronic semiconductor chip,
wherein the covering body is at least partly covered by the wavelength-converting element.

17. The method according to claim 16, wherein the covering body is formed by a dispensing method.

18. The method according to claim 17, wherein the dispensing method is a needle dispensing method.

19. The method according to claim 17, wherein a material of the covering body completely wets the electrical contact pad.

20. The method according to claim 16, wherein the wavelength-converting element is formed by a spray method.

21. The method according to claim 16, further comprising:
before forming the covering body, arranging the optoelectronic semiconductor chip on a top side of a carrier such that the top side of the optoelectronic semiconductor chip faces away from the top side of the carrier; and
forming an embedding body on the top side of the carrier, wherein side faces of the optoelectronic semiconductor chip are at least partly covered by the embedding body.

22. The method according to claim 21,
wherein the covering body and the embedding body are formed in a common operation.

23. The method according to claim 16, further comprising forming an optical lens over the wavelength-converting element.

24. An optoelectronic device comprising:
an optoelectronic semiconductor chip having an electrical contact pad arranged on a top side;
a bond wire connected to the electrical contact pad;
a covering body arranged on the electrical contact pad, wherein the covering body is limited to the electrical contact pad and does not cover other portions of the top side of the optoelectronic semiconductor chip, and wherein the bond wire is partially embedded in the covering body; and
a wavelength-converting element arranged on the top side of the optoelectronic semiconductor chip,
wherein the covering body is at least partly covered by the wavelength-converting element.

25. The optoelectronic device according to claim 24, wherein the electrical contact pad is completely covered by the covering body.

26. The optoelectronic device according to claim 24, wherein the covering body comprises a silicone.

27. The optoelectronic device according to claim 24, wherein the covering body comprises embedded particles.

28. The optoelectronic device according to claim 27, wherein the embedded particular comprise TiO₂ or ZrO₂.

29. The optoelectronic device according to claim 24, wherein side faces of the optoelectronic semiconductor chip are at least partly covered by an embedding body.

30. The optoelectronic device according to claim 24, further comprising an optical lens arranged over the wavelength-converting element.
